(19) United States
(12) Patent Application Publication
(10) Pub. No.: US 2025/0386567 A1
(43) Pub. Date: Dec. 18, 2025

(54) STACKED FIELD EFFECT TRANSISTOR WITH ANGLED CONTACTS AND LOCAL INTERCONNECTS

(71) Applicant: International Business Machines Corporation, Armonk, NY (US)

(72) Inventors: Min Gyu Sung, Latham, NY (US); Oleg Gluschenkov, Tannersville, NY (US); Julien Frougier, Albany, NY (US); Ruilong Xie, Niskayuna, NY (US); Andrew Mark Greene, Slingerlands, NY (US); Susan Ng Emans, Albany, NY (US)

(21) Appl. No.: 18/744,933

(22) Filed: Jun. 17, 2024

(51) Int. Cl. H01L 29/08; H01L 21/822; H01L 21/8234; H01L 27/06; H01L 27/088; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 84/013; H10D 84/038; H10D 84/83; H10D 88/00; H10D 88/01

(57) ABSTRACT

A semiconductor device fabrication method is provided and includes fabricating a bottom field effect transistor (FET) with bottom source/drain (S/D) epitaxy on a substrate, fabricating a top FET with top S/D epitaxy over the bottom FET to form a stacked FET, surrounding the stacked FET with dielectric material, angled etching through at least the dielectric material to form an angled contact opening from the bottom S/D epitaxy and executing contact metallization to form, in the angled contact opening, an angled contact extending from the bottom S/D epitaxy.

### BACKGROUND

The present disclosure generally relates to fabrication methods and resulting structures for semiconductor devices. More specifically, the present disclosure relates to stacked field effect transistors (FETs) with angled contacts and local interconnects.

A transistor is a semiconductor device used to amplify or switch electrical signals and power and is one of the basic building blocks of modern electronics. A field-effect transistor (FET) is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a semiconductor device fabrication method is provided and includes fabricating a bottom field effect transistor (FET) with bottom source/drain (S/D) epitaxy on a substrate, fabricating a top FET with top S/D epitaxy over the bottom FET to form a stacked FET, surrounding the stacked FET with dielectric material, angled etching through at least the dielectric material to form an angled contact opening from the bottom S/D epitaxy and executing contact metallization to form, in the angled contact opening, an angled contact extending from the bottom S/D epitaxy. In additional or alternative embodiments, the semiconductor device fabrication method provides for a semiconductor device with angled contacts and a reduced risk of a short between the angled contacts and proximal epitaxy.

According to an aspect of the disclosure, a semiconductor device is provided and includes a stacked field effect transistor (FET) including a bottom FET with bottom source/drain (S/D) epitaxy and a top FET with top S/D epitaxy stacked over the bottom FET, a back-end-of-line (BEOL) layer disposed above the stacked FET, a first contact extending upwardly from the top S/D epitaxy to the BEOL layer and a second contact extending upwardly from the bottom S/D epitaxy to the BEOL layer. The second contact includes a lower angled contact having a first slope angle and an upper angled contact having a second slope angle differing from the first slope angle. In additional or alternative embodiments, the semiconductor device is provided with the angled contacts and a reduced risk of a short between the angled contacts and proximal epitaxy.

According to an aspect of the disclosure, a semiconductor device is provided and includes first and second stacked field effect transistors (FETs) each including a bottom FET with bottom source/drain (S/D) epitaxy and a top FET with top S/D epitaxy stacked over the bottom FET, a back-end-of-line (BEOL) layer disposed above the first and second stacked FETs, first contacts extending upwardly from the bottom S/D epitaxy of the first stacked FET and upwardly from the top S/D epitaxy of the second stacked FET to the BEOL layer and an angled second contact extending at an angle upwardly from the bottom S/D epitaxy of the second stacked FET to the top S/D epitaxy of the first stacked FET. In additional or alternative embodiments, the semiconductor device is provided with the angled contacts and a reduced risk of a short between the angled contacts and proximal epitaxy.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side view of a semiconductor device with first and second angled contacts in accordance with one or more embodiments;

FIG. 2 is a side view of a semiconductor device with an angled contact with a lower angled contact and an upper angled contact in accordance with one or more embodiments;

FIG. 3 is a side view of a semiconductor device with a single angled contact in accordance with one or more embodiments;

FIG. 4 is a flow diagram illustrating a semiconductor device fabrication method in accordance with one or more embodiments;

FIG. 5 is a top-down view of a semiconductor device in accordance with one or more embodiments;

FIG. 6 is a set of images illustrating a fabrication method of a semiconductor device with first and second angled contacts in accordance with one or more embodiments;

FIG. 7 is a set of images illustrating a fabrication method of a semiconductor device with an angled contact with a lower angled contact and an upper angled contact in accordance with one or more embodiments; and

FIG. 8 is a set of images illustrating a fabrication method of a semiconductor device with a single angled contact in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device fabrication method is provided and includes fabricating a bottom field effect transistor (FET) with bottom source/drain (S/D) epitaxy on a substrate, fabricating a top FET with top S/D epitaxy over the bottom FET to form a stacked FET, surrounding the stacked FET with dielectric material, angled etching through at least the dielectric material to form an angled contact opening from the bottom S/D epitaxy and executing contact metallization to form, in the angled contact opening, an angled contact extending from the bottom S/D epitaxy. In additional or alternative embodiments, the semiconductor device fabrication method provides for a semiconductor device with angled contacts and a reduced risk of a short between the angled contacts and proximal epitaxy.

In accordance with additional or alternative embodiments, the angled etching includes directional reactive ion etching (RIE) to form the angled contact opening.

In accordance with additional or alternative embodiments, the angled etching is executed at an angle of up to about 45 degrees to form the angled contact openings and the angled contacts in a controlled manner with a sufficient angled to reduce the risk of a short.

In accordance with additional or alternative embodiments, the angled etching includes angled etching in a first direction to form a lower angled contact opening and angled etching in a second direction opposite the first direction to form an upper angled contact opening communicative with the lower angled contact opening so that the upper and lower angled contacts can have an hourglass shape and a safe distance from epitaxy.

In accordance with additional or alternative embodiments, the angled etching includes angled etching in a first direction and at a first slope angle to form a lower angled contact opening having the first slope angle and angled etching in a second direction and at a second slope angle to form an upper angled contact opening having the second slope angle and being communicative with the lower angled contact opening so that the upper and lower angled contacts can have a safe distance from epitaxy.

In accordance with additional or alternative embodiments, the angled etching includes angled etching to form a single angled contact opening from the bottom S/D epitaxy and through top S/D epitaxy of a neighboring stacked FET so that the single angled contact can have a safe distance from epitaxy.

According to an aspect of the disclosure, a semiconductor device is provided and includes a stacked field effect transistor (FET) including a bottom FET with bottom source/drain (S/D) epitaxy and a top FET with top S/D epitaxy stacked over the bottom FET, a back-end-of-line (BEOL) layer disposed above the stacked FET, a first contact extending upwardly from the top S/D epitaxy to the BEOL layer and a second contact extending upwardly from the bottom S/D epitaxy to the BEOL layer. The second contact includes a lower angled contact having a first slope angle and an upper angled contact having a second slope angle differing from the first slope angle. In additional or alternative embodiments, the semiconductor device is provided with the angled contacts and a reduced risk of a short between the angled contacts and proximal epitaxy.

In accordance with additional or alternative embodiments, a minimum distance between the upper angled contact and the top S/D epitaxy is about 5 to 10 nm and provides for a reduced risk of a short between an angled contact and proximal epitaxy.

In accordance with additional or alternative embodiments, the upper angled contact lands over the lower angled contact which provides for a compact structure.

In accordance with additional or alternative embodiments, the upper angled contact and the lower angled contact are angled in opposite directions which provides for a compact structure and an hourglass shape.

In accordance with additional or alternative embodiments, the stacked FET is a first stacked FET and the semiconductor device further includes a second stacked FET neighboring the first stacked FET and including another bottom FET with another bottom S/D epitaxy and another top FET with another top S/D epitaxy stacked over the another bottom FET, a third contact extending upwardly from the another top S/D epitaxy of the second stacked FET to the BEOL layer and a fourth contact extending upwardly from the another bottom S/D epitaxy of the second stacked FET to the BEOL layer, the fourth contact including a lower angled contact having a first slope angle and an upper angled contact having a second slope angle differing from the first slope angle. The semiconductor device is thus compact and is provided with the angled contacts and a reduced risk of a short between the angled contacts and proximal epitaxy.

In accordance with additional or alternative embodiments, the second and fourth contacts form an hourglass-shaped cross-section for a compact structure.

In accordance with additional or alternative embodiments, the upper angled contact of the second contact and the upper angled contact of the fourth contact are angled away from one another, the lower angled contact of the second contact and the lower angled contact of the fourth contact are angled toward one another and a minimum distance between the second and fourth contacts is about 5 to 10 nm which is a sufficient distance to reduce a risk of a short.

According to an aspect of the disclosure, a semiconductor device is provided and includes first and second stacked field effect transistors (FETs) each including a bottom FET with bottom source/drain (S/D) epitaxy and a top FET with top S/D epitaxy stacked over the bottom FET, a back-end-of-line (BEOL) layer disposed above the first and second stacked FETs, first contacts extending upwardly from the bottom S/D epitaxy of the first stacked FET and upwardly from the top S/D epitaxy of the second stacked FET to the BEOL layer and an angled second contact extending at an angle upwardly from the bottom S/D epitaxy of the second stacked FET to the top S/D epitaxy of the first stacked FET. In additional or alternative embodiments, the semiconductor device is provided with the angled contacts and a reduced risk of a short between the angled contacts and proximal epitaxy.

In accordance with additional or alternative embodiments, the angled second contact includes a lower angled contact having a first slope angle and an upper angled contact having a second slope angle differing from the first slope angle to provide for a reduced risk of a short between the lower angled contact and proximal epitaxy and between the upper angled contact and proximal epitaxy.

In accordance with additional or alternative embodiments, the lower angled contact has a shallower angle than the upper angled contact to avoid being too close to upper epitaxy.

In accordance with additional or alternative embodiments, a minimum distance between the lower angled contact and the bottom S/D epitaxy of the first stacked FET is about 5 to 20 nm and a minimum distance between the upper angled contact and the top S/D epitaxy of the second stacked FET is about 5 to 20 nm which is a sufficient distance to reduce a risk of a short between the lower and upper angled contacts and proximal epitaxy.

In accordance with additional or alternative embodiments, the angled second contact is a single angled contact and extends at a single angle from a side of the bottom

S/D epitaxy of the second stacked FET and through the top S/D epitaxy of the first stacked FET with a reduced risk of a short between the single angled contact and proximal epitaxy.

In accordance with additional or alternative embodiments, a local entirety of the single angled contact pierces through the top S/D epitaxy of the first stacked FET to provide for a compact structure.

In accordance with additional or alternative embodiments, a minimum distance between the single angled contact and the bottom S/D epitaxy of the first stacked FET is about 5 to 10 nm and a minimum distance between the single angled contact and the top S/D epitaxy of the second stacked FET is about 5 to 10 nm with a reduced risk of a short between the single angled contact and proximal epitaxy.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, a stacked FET is characterized as having a bottom FET with bottom source/drain (S/D) epitaxy disposed on a substrate and a top FET with top S/D epitaxy disposed over the bottom FET. Dielectric material, such as interlayer dielectric (ILD) and bonding oxide can be vertically interposed between the bottom FET and the top FET. The bottom S/D epitaxy and the top S/D epitaxy of a given stacked FET can be considered a cell and each cell can be disposed next to a neighboring cell.

Due to front-end-of-line (FEOL)/middle-of-line (MOL) congestion in a stacked FET of recent semiconductor device designs, connecting the top S/D epitaxy of a cell to the bottom S/D epitaxy of a same cell or to the bottom S/D epitaxy of a neighboring cell has been difficult.

In the former case, connecting the top S/D epitaxy of a cell of a stacked FET to the bottom S/D epitaxy of the same cell is usually accomplished by forming a vertical contact extending vertically upward to a back-end-of-line (BEOL) layer from the bottom S/D epitaxy. This vertical contact tends to pass the top S/D epitaxy with relatively little space and presents a risk of a short between a side of the vertical contact and a proximal side of the top S/D epitaxy.

In the latter case, connecting the top S/D epitaxy of a cell of a stacked FET to the bottom S/D epitaxy of a neighboring cell of another stacked FET is usually accomplished by wiring the top S/D epitaxy of the cell to a back-end-of-line (BEOL) layer through a first connection and by separately wiring the bottom S/D epitaxy to the BEOL layer through a second connection and then forming a connection through a metallization layer. This tends to be area consuming and inefficient especially where the first and second connections are relatively far from one another (i.e., where the top S/D epitaxy of the neighboring cell is horizontally interposed between the first and second connections).

Prior solutions to the problem of connecting the top S/D epitaxy of a cell to the bottom S/D epitaxy of a neighboring cell have been proposed but present drawbacks. In one solution, a vertical contact is formed to extend downwardly from and along a side of the top S/D epitaxy of a first cell and a horizontal contact is formed from a bottom end of the vertical contact to the bottom S/D epitaxy of a neighboring second cell. This presents a risk of shorting between the bottom end of the vertical contact and the bottom S/D epitaxy of the first cell. In another solution, the vertical contact is moved away from the top S/D epitaxy of the first cell and toward the top S/D epitaxy of the neighboring second cell. While this removes risk of shorting between the bottom end of the vertical contact and the bottom S/D epitaxy of the first cell, there is now a risk of shorting between the vertical contact and the top S/D epitaxy of the neighboring second cell.

Turning now to an overview of the aspects of the disclosure, one or more embodiments of the disclosure address the above-described shortcomings of the prior art by providing semiconductor devices. In one semiconductor device, the semiconductor device includes top S/D epitaxy of a top FET stacked vertically over bottom S/D epitaxy of a bottom FET, an angled bottom contact and an angled top contact. The angled top contact can land over the angled bottom contact by way of the angled top contact and the angled bottom contact being angled in opposite directions. In another semiconductor device, the semiconductor device includes top S/D epitaxy of a top FET stacked vertically over bottom S/D epitaxy of a bottom FET in a first cell of a first stacked FET, top S/D epitaxy of a top FET stacked vertically over bottom S/D epitaxy of a bottom FET in a second cell of a second stacked FET and an angled contact connecting the top S/D epitaxy of the first cell with the bottom S/D epitaxy of the second cell where the first and second cells are neighboring cells. The angled contact can include an upper angled contact and a lower angled contact with differing slopes. Alternatively, the angled contact can be a single sloped contact that extends through the top S/D epitaxy of the first cell to a side of the bottom S/D epitaxy of the second cell.

The above-described aspects of the disclosure address the shortcomings of the prior art by providing for semiconductor devices with angled contacts that avoid shorting risks between contacts and S/D epitaxy.

In one or more embodiments, the semiconductor device includes a stacked FET including a bottom FET with bottom S/D epitaxy and a top FET with top S/D epitaxy stacked over the bottom FET, a BEOL layer disposed above the stacked FET, a first contact extending upwardly from the top S/D epitaxy to the BEOL layer and a second contact extending upwardly from the bottom S/D epitaxy to the BEOL layer. The second contact includes a lower angled contact having a first slope angle and an upper angled contact having a second slope angle differing from the first slope angle.

In one or more embodiments, the semiconductor device includes first and second stacked FETs each including a bottom FET with bottom S/D epitaxy and a top FET with top S/D epitaxy stacked over the bottom FET, a BEOL layer disposed above the first and second stacked FETs, first contacts extending upwardly from the bottom S/D epitaxy of the first stacked FET and upwardly from the top S/D epitaxy of the second stacked FET to the BEOL layer and an angled second contact extending at an angle upwardly from the bottom S/D epitaxy of the second stacked FET to the top S/D epitaxy of the first stacked FET.

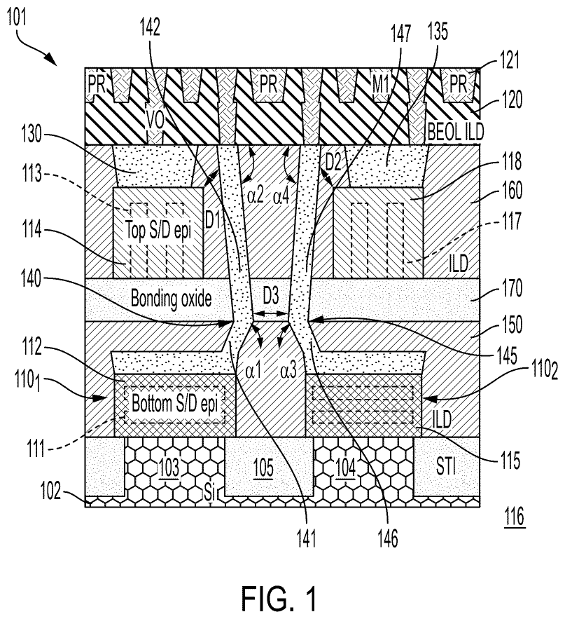

Turning now to a more detailed description of aspects of the present disclosure, FIG. 1, a semiconductor device 101 is provided and includes a substrate 102 with pillars 103 and 104, shallow trench isolation (STI) 105 interposed between the pillars 103 and 104 and a stacked FET that can also be referred to as first stacked FET 1101. The stacked FET (e.g., the first stacked FET 1101) is disposed on pillar 103 and includes a bottom FET 111 (i.e., a nanosheet FET) with bottom S/D epitaxy 112 and a top FET 113 (i.e., a FINFET) with top S/D epitaxy 114 stacked over the bottom FET 111. The semiconductor device 101 further includes a BEOL layer 120 and metallization 121 disposed above the stacked FET (e.g., the first stacked FET 1101), a first contact 130 and a second contact 140. Lower ILD 150 surrounds the bottom FET 111, upper ILD 160 surrounds the top FET 113 and bonding oxide 170 is provided between the bottom FET 111 and the top FET 113. The first contact 130 extends upwardly from the top S/D epitaxy 114 to the BEOL layer 120. The second contact 140 extends upwardly from the bottom S/D epitaxy 112 to the BEOL layer 120 and includes a lower angled contact 141 and an upper angled contact 142. The lower angled contact 141 extends upwardly from the bottom S/D epitaxy 112 and through the lower ILD 150. The lower angled contact 141 has a first slope angle α1. The (second) upper angled contact 142 extends upwardly from an end of the lower angled contact 141, through the bonding oxide 170 and the upper ILD 160 and to the BEOL layer 120. The upper angled contact 142 has a second slope angle α2. The second slope angle α2 differs from the first slope angle α1.

As shown in FIG. 1, the upper angled contact 142 lands over the lower angled contact 141 due in part to the upper angled contact 142 and the lower angled contact 141 being angled in opposite directions (i.e., positive and negative directions).

With the second contact 140 including the lower angled contact 141 and the upper angled contact 142, a minimum distance D1 between the upper angled contact 142 and the top S/D epitaxy 114 can be controlled by controlling the first slope angle α1 and the second slope angle α2 whereby a risk of a short between the upper angled contact 142 and the top S/D epitaxy 114 can be reduced. In accordance with one or more embodiments, the minimum distance D1 can be about 5 to 10 nm.

With continued reference to FIG. 1, again the stacked FET can be provided as the first stacked FET 1101. In these or other cases, the semiconductor device 101 can further include a second stacked FET 1102 neighboring the first stacked FET 1101 and including a bottom FET 115 with bottom S/D epitaxy 116 and a top FET 117 with top S/D epitaxy 118 stacked over the bottom FET 115. Here, the bottom FET 111 and the top FET 113 can form a first cell and the bottom FET 115 and the top FET 117 can form a second cell neighboring the first cell. The semiconductor device 101 also includes third contact 135 and a fourth contact 145. The lower ILD 150 surrounds the bottom FET 115, the upper ILD 160 surrounds the top FET 117 and the bonding oxide 170 is provided between the bottom FET 115 and the top FET 117. The third contact 135 extends upwardly from the top S/D epitaxy 118 to the BEOL layer 120. The fourth contact 145 extends upwardly from the bottom S/D epitaxy 116 to the BEOL layer 120 and includes a lower angled contact 146 and an upper angled contact 147. The lower angled contact 146 extends upwardly from the bottom S/D epitaxy 116 and through the lower ILD 150. The lower angled contact 146 has a first slope angle α3. The (second) upper angled contact 147 extends upwardly from an end of the lower angled contact 143, through the bonding oxide 170 and the upper ILD 160 and to the BEOL layer 120. The upper angled contact 147 has a second slope angle α4. The second slope angle α4 differs from the first slope angle α3.

As shown in FIG. 1, the upper angled contact 147 lands over the lower angled contact 146 due in part to the upper angled contact 147 and the lower angled contact 146 being angled in opposite directions (i.e., positive and negative directions).

With the fourth contact 145 including the lower angled contact 146 and the upper angled contact 147, a minimum distance D2 between the upper angled contact 146 and the top S/D epitaxy 118 can be controlled by controlling the third slope angle α3 and the fourth slope angle α4 whereby a risk of a short between the upper angled contact 147 and the top S/D epitaxy 118 can be reduced. In accordance with one or more embodiments, the minimum distance D2 can be about 5 to 10 nm.

As shown in FIG. 1 and in accordance with one or more embodiments, the second contact 140 and the fourth contact 145 can cooperatively form an hourglass-shaped cross-section with the upper angled contacts 142 and 147 angled away from one another and the lower angled contacts 141 and 146 angled toward one another and with a minimum distance D3 between the second and fourth contacts 140 and 145 being about 5 to 10 nm.

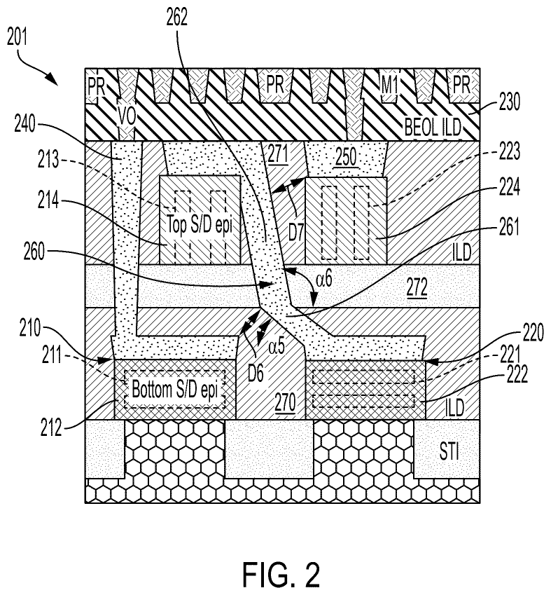

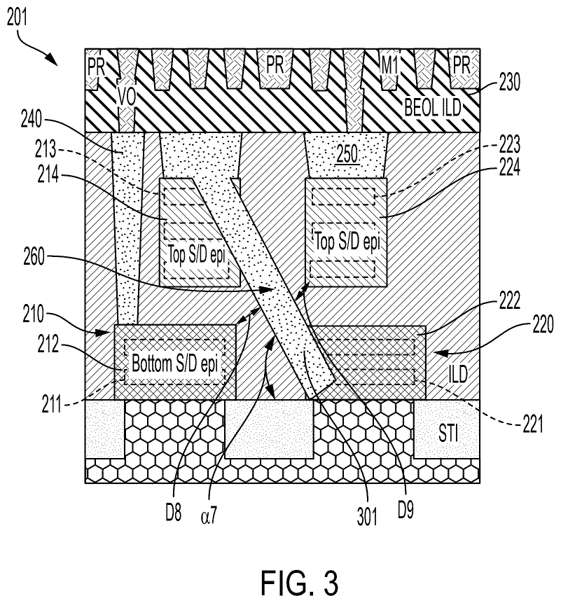

With reference to FIGS. 2 and 3, a semiconductor device 201 is provided and includes first and second stacked FETs 210, 220 that each include a bottom FET 211, 221 with bottom S/D epitaxy 212, 222 and a top FET 213, 223 with top S/D epitaxy 214, 224 stacked over the bottom FET 211, 221. The semiconductor device 201 further includes a BEOL layer 230 layer disposed above the first and second stacked FETs 210, 220, first contacts 240, 250, an angled second contact 260, lower ILD 270, upper ILD 271 and bonding oxide 272. The lower ILD 270 surrounds the bottom FETs 211, 221, the upper ILD 271 surrounds the top FETs 213, 223 and the bonding oxide 272 is provided between the bottom FETs 211, 221 and the top FETs 213, 223. The first contact 240 extends upwardly from the bottom S/D epitaxy 212 of the first stacked FET 210, through the lower ILD 270, the bonding oxide 272 and the upper ILD 271 and to the BEOL layer 230. The first contact 250 extends upwardly from the top S/D epitaxy 224 of the second stacked FET 220, through the upper ILD 271 and to the BEOL layer 230. The angled second contact 260 extends at an angle upwardly from the bottom S/D epitaxy 222 of the second stacked FET 220, through the lower ILD 270, the bonding oxide 272 and the upper ILD 271 and to the top S/D epitaxy 214 of the first stacked FET 210.

As shown in FIG. 2 and in accordance with one or more embodiments, the angled second contact 260 can include a lower angled contact 261 extending upwardly from the bottom S/D epitaxy 222 and through the lower ILD 270 and having a first slope angle α5 and an upper angled contact 262 extending from an end of the lower angled contact 261, through the boding oxide 272 and the upper ILD 271 and having a second slope angle α6 differing from the first slope angle α5. The lower angled contact 261 can have a shallower angle than the upper angled contact 262.

With the angled second contact 260 including the lower angled contact 261 and the upper angled contact 262, a minimum distance D6 between the lower angled contact 261 and the bottom S/D epitaxy 212 of the first stacked FET 210 can be about 5 to 20 nm whereby a risk of a short between the lower angled contact 261 and the bottom S/D epitaxy 212 can be reduced and a minimum distance D7 between the upper angled contact 262 and the top S/D epitaxy 224 of the second stacked FET 220 can be about 5 to 20 nm whereby a risk of a short between the upper angled contact 262 and the top S/D epitaxy 224 can be reduced.

As shown in FIG. 3 and in accordance with one or more embodiments, the angled second contact 260 can be provided as a single angled contact 301 and extends at a single angle α7 from a side of the bottom S/D epitaxy 222 of the second stacked FET 220 and through the top S/D epitaxy 214 of the first stacked FET 210.

With the angled second contact 260 provided as the single angled contact 301, a local entirety of the single angled contact 301 can be configured to pierce through the top S/D epitaxy 214. Here, a minimum distance D8 between the single angled contact 301 and the bottom S/D epitaxy 212 of the first stacked FET 210 can be about 5 to 10 nm and a minimum distance D9 between the single angled contact 301 and the top S/D epitaxy 224 of the second stacked FET 220 can be about 5 to 10 nm.

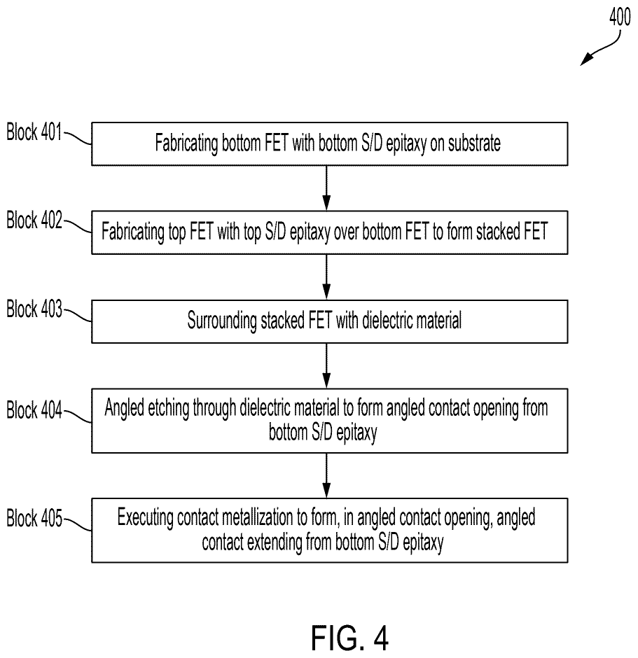

With reference to FIG. 4, a semiconductor device fabrication method 400 is provided and includes fabricating a bottom FET with bottom S/D epitaxy on a substrate (block 401), fabricating a top FET with top S/D epitaxy over the bottom FET to form a stacked FET (block 402), surrounding the stacked FET with dielectric material (block 403), angled etching through at least the dielectric material to form an angled contact opening from the bottom S/D epitaxy (block 404) and executing contact metallization to form, in the angled contact opening, an angled contact extending from the bottom S/D epitaxy (block 405). In accordance with one or more embodiments, the angled etching of block 404 can include directional reactive ion etching (RIE) and can be executed at an angle of up to about 45 degrees or more.

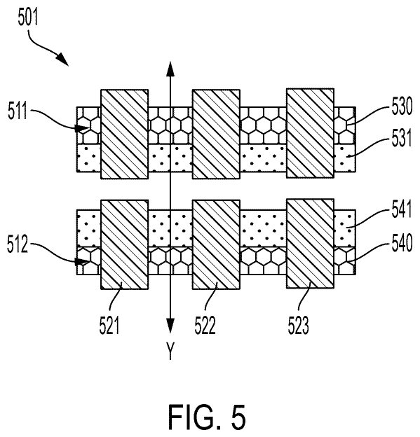

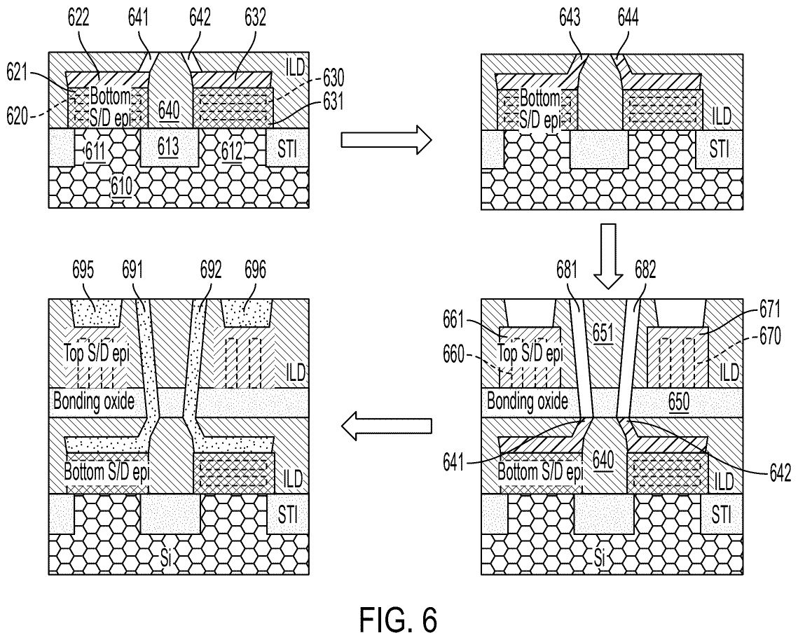

With continued reference to FIG. 4 and with additional reference to FIG. 5 and to FIGS. 6-8, the semiconductor device fabrication method 400 of FIG. 4 will now be described in greater detail.

FIG. 5 depicts a top-down view of a semiconductor device 501 to be fabricated. FIGS. 6-8 are side views of the semiconductor device 501 each in accordance with one or more embodiments and each taken from a perspective defined by cross-sectional view Y of FIG. 5.

As shown in FIG. 5, the semiconductor device 501 includes a first stacked nanosheet device channel 511 and a second stacked nanosheet device channel 512 as well as first, second and third gates 521, 522, 523 respectively crossing each of the first stacked nanosheet device channel 511 and the second stacked nanosheet device channel 512. The first stacked nanosheet device channel 511 includes a bottom device 530 and a top device 531. The second stacked nanosheet device channel 512 includes a bottom device 540 and a top device 541.

As shown in the first image of FIG. 6, a semiconductor device fabrication method in accordance with one or more embodiments includes forming a substrate 610 with pillars 611 and 612 and STI 613 between the pillars 611 and 612, a bottom FET 620 with bottom S/D epitaxy 621 and placeholder material 622 of a first stacked nanosheet FET, a bottom FET 630 with bottom S/D epitaxy 631 and placeholder material 632 and dielectric material 640 surrounding the bottom FET 620 and the bottom FET 630. The first image of FIG. 6 further illustrates that lower angled contact openings 641 and 642 are formed in the dielectric material 640 from the placeholder material 622 and 632, respectively, by angled etching to be angled toward one another. The second image of FIG. 6 illustrates that additional placeholder material 643 and 644 is formed in the lower angled contact openings 641 and 642. The third image of FIG. 6 illustrates that bonding oxide 650 is formed over the dielectric material 640, that a top FET 660 with top S/D epitaxy 661 is formed over the bottom FET 620, that a top FET 670 with top S/D epitaxy 671 is formed over the bottom FET 630 and that additional dielectric material 651 is formed to surround the top FET 660 and the top FET 670. In addition, the third image of FIG. 6 illustrates that upper angled contact openings 681 and 682 are formed to extend from ends of the lower angled contact openings 641 and 642, respectively, by angled etching to be angled away from each other. The fourth image of FIG. 6 illustrates the removal of placeholder material and the formation of contacts 691 and 692 respectively in the lower angled contact openings 641 and 642 and respectively in the upper angled contact openings 681 and 682 as well as the formation of contacts 695 and 696 extending upwardly from the top S/D epitaxy 661 and 671.

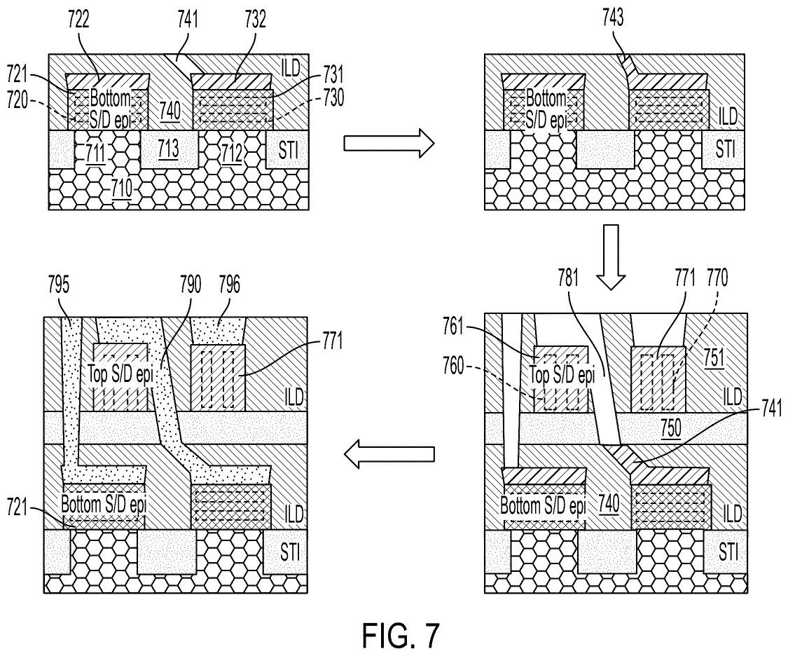

As shown in the first image of FIG. 7, a semiconductor device fabrication method in accordance with one or more embodiments includes forming a substrate 710 with pillars 711 and 712 and STI 713 between the pillars 711 and 712, a bottom FET 720 with bottom S/D epitaxy 721 and placeholder material 722 of a first stacked nanosheet FET, a bottom FET 730 with bottom S/D epitaxy 731 and placeholder material 732 and dielectric material 740 surrounding the bottom FET 720 and the bottom FET 730. The first image of FIG. 7 further illustrates that a lower angled contact opening 741 is formed in the dielectric material 740 from the placeholder material 732, respectively, by angled etching to be angled at a first slope angle. The second image of FIG. 7 illustrates that additional placeholder material 743 is formed in the lower angled contact opening 741. The third image of FIG. 7 illustrates that bonding oxide 750 is formed over the dielectric material 740, that a top FET 760 with top S/D epitaxy 761 is formed over the bottom FET 720, that a top FET 770 with top S/D epitaxy 771 is formed over the bottom FET 730 and that additional dielectric material 751 is formed to surround the top FET 760 and the top FET 770. In addition, the third image of FIG. 7 illustrates that upper angled contact opening 781 is formed to extend from an end of the lower angled contact opening 741 by angled etching to be angled at a second slope angle. The fourth image of FIG. 7 illustrates the removal of placeholder material and the formation of contact 790 respectively in the lower and upper angled contact openings 741 and 781 as well as the formation of contacts 795 and 796 extending upwardly from the bottom S/D epitaxy 721 and the top S/D epitaxy 771.

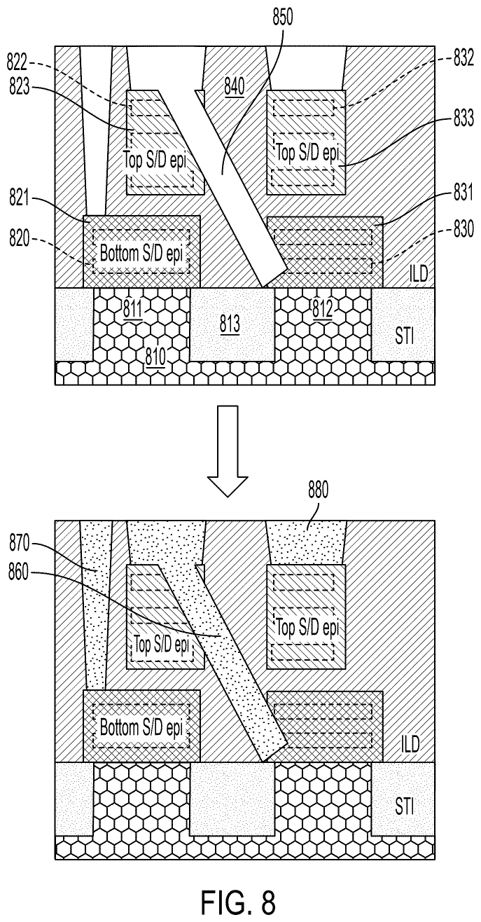

As shown in the first image of FIG. 8, a semiconductor device fabrication method in accordance with one or more embodiments includes forming a substrate 810 with pillars 811 and 812 and STI 813 between the pillars 811 and 812, a bottom FET 820 with bottom S/D epitaxy 821 and a top FET 822 with top S/D epitaxy 823 forming a first stacked nanosheet FET and a bottom FET 830 with bottom S/D epitaxy 831 and a top FET 832 with top S/D epitaxy 833 forming a second stacked nanosheet FET and dielectric material 840 surrounding the first and second nanosheet FETs. The first image of FIG. 8 further illustrates that a single angled contact opening 850 is formed to extend through the top FET 822, the dielectric material 840 and to the bottom FET 830 by angled etching to be angled at a single slope angle. The second image of FIG. 8 illustrates the formation of contact 860 in the single angled contact opening 850 as well as the formation of contacts 870 and 880 extending upwardly from the bottom S/D epitaxy 821 and the top S/D epitaxy 833.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device fabrication method, comprising:
fabricating a bottom field effect transistor (FET) with bottom source/drain (S/D) epitaxy on a substrate;
fabricating a top FET with top S/D epitaxy over the bottom FET to form a stacked FET;
surrounding the stacked FET with dielectric material;
angled etching through at least the dielectric material to form an angled contact opening from the bottom S/D epitaxy; and
executing contact metallization to form, in the angled contact opening, an angled contact extending from the bottom S/D epitaxy.

2. The semiconductor device fabrication method according to claim 1, wherein the angled etching comprises directional reactive ion etching (RIE).

3. The semiconductor device fabrication method according to claim 1, wherein the angled etching is executed at an angle of up to about 45 degrees.

4. The semiconductor device fabrication method according to claim 1, wherein the angled etching comprises:
angled etching in a first direction to form a lower angled contact opening; and
angled etching in a second direction opposite the first direction to form an upper angled contact opening communicative with the lower angled contact opening.

5. The semiconductor device fabrication method according to claim 1, wherein the angled etching comprises:
angled etching in a first direction and at a first slope angle to form a lower angled contact opening having the first slope angle; and
angled etching in a second direction and at a second slope angle to form an upper angled contact opening having the second slope angle and being communicative with the lower angled contact opening.

6. The semiconductor device fabrication method according to claim 1, wherein the angled etching comprises angled etching to form a single angled contact opening from the bottom S/D epitaxy and through top S/D epitaxy of a neighboring stacked FET.

7. A semiconductor device, comprising:
a stacked field effect transistor (FET) comprising a bottom FET with bottom source/drain (S/D) epitaxy and a top FET with top S/D epitaxy stacked over the bottom FET;
a back-end-of-line (BEOL) layer disposed above the stacked FET;
a first contact extending upwardly from the top S/D epitaxy to the BEOL layer; and
a second contact extending upwardly from the bottom S/D epitaxy to the BEOL layer, the second contact comprising:
a lower angled contact having a first slope angle; and
an upper angled contact having a second slope angle differing from the first slope angle.

8. The semiconductor device according to claim 7, wherein a minimum distance between the upper angled contact and the top S/D epitaxy is about 5 to 10 nm.

9. The semiconductor device according to claim 7, wherein the upper angled contact lands over the lower angled contact.

10. The semiconductor device according to claim 7, wherein the upper angled contact and the lower angled contact are angled in opposite directions.

11. The semiconductor device according to claim 7, wherein the stacked FET is a first stacked FET and the semiconductor device further comprises:
a second stacked FET neighboring the first stacked FET and comprising another bottom FET with another bottom S/D epitaxy and another top FET with another top S/D epitaxy stacked over the another bottom FET;
a third contact extending upwardly from the another top S/D epitaxy of the second stacked FET to the BEOL layer; and
a fourth contact extending upwardly from the another bottom S/D epitaxy of the second stacked FET to the BEOL layer, the fourth contact comprising a lower angled contact having a first slope angle and an upper angled contact having a second slope angle differing from the first slope angle.

12. The semiconductor device according to claim 11, wherein the second and fourth contacts form an hourglass-shaped cross-section.

13. The semiconductor device according to claim 11, wherein:
the upper angled contact of the second contact and the upper angled contact of the fourth contact are angled away from one another,
the lower angled contact of the second contact and the lower angled contact of the fourth contact are angled toward one another, and
a minimum distance between the second and fourth contacts is about 5 to 10 nm.

14. A semiconductor device, comprising:
first and second stacked field effect transistors (FETs) each comprising a bottom FET with bottom source/drain (S/D) epitaxy and a top FET with top S/D epitaxy stacked over the bottom FET;
a back-end-of-line (BEOL) layer disposed above the first and second stacked FETs;
first contacts extending upwardly from the bottom S/D epitaxy of the first stacked FET and upwardly from the top S/D epitaxy of the second stacked FET to the BEOL layer; and
an angled second contact extending at an angle upwardly from the bottom S/D epitaxy of the second stacked FET to the top S/D epitaxy of the first stacked FET.

15. The semiconductor device according to claim 14, wherein the angled second contact comprises:
a lower angled contact having a first slope angle; and
an upper angled contact having a second slope angle differing from the first slope angle.

16. The semiconductor device according to claim 14, wherein the lower angled contact has a shallower angle than the upper angled contact.

17. The semiconductor device according to claim 14, wherein:
a minimum distance between the lower angled contact and the bottom S/D epitaxy of the first stacked FET is about 5 to 20 nm, and a minimum distance between the upper angled contact and the top S/D epitaxy of the second stacked FET is about 5 to 20 nm.

18. The semiconductor device according to claim 14, wherein the angled second contact is a single angled contact and extends at a single angle from a side of the bottom S/D epitaxy of the second stacked FET and through the top S/D epitaxy of the first stacked FET.

19. The semiconductor device according to claim 18, wherein a local entirety of the single angled contact pierces through the top S/D epitaxy of the first stacked FET.

20. The semiconductor device according to claim 18, wherein:
a minimum distance between the single angled contact and the bottom S/D epitaxy of the first stacked FET is about 5 to 10 nm, and
a minimum distance between the single angled contact and the top S/D epitaxy of the second stacked FET is about 5 to 10 nm.
